(19) United States
(12) Patent Application Publication
(10) Pub. No.: US 2026/0064587 A1
(43) Pub. Date: Mar. 5, 2026

(54) SYSTEM AND METHOD FOR DYNAMIC WEAR LEVELING

(71) Applicant: Microchip Technology Incorporated, Chandler, AZ (US)

(72) Inventors: Hayes Hsueh, San Jose, CA (US); Pitamber Shukla, San Jose, CA (US); Srinivas Yelisetti, Fremont, CA (US)

(73) Assignee: Microchip Technology Incorporated, Chandler, AZ (US)

(21) Appl. No.: 18/999,434

(22) Filed: Dec. 23, 2024

Related U.S. Application Data
(60) Provisional application No. 63/687,644, filed on Aug. 27, 2024.

(51) Int. Cl. G06F 12/02

(52) U.S. Cl. CPC G06F 12/0246; G06F 2212/7211

(57) ABSTRACT

A data storage system may include a memory device and a controller. The memory device may include a plurality of virtual blocks. The controller may include at least one processor and a memory. The memory may include instructions stored thereon, that when that when executed by the at least one processor, cause the at least one processor to: monitor a number of program/erase cycles for the plurality of virtual blocks; collect read errors for the plurality of virtual blocks; select a virtual block of the plurality of virtual blocks to open based on the number of program/erase cycles and the collected read errors; and write data to the selected open virtual block.

### CROSS-REFERENCE TO RELATED APPLICATIONS

The current patent application claims the benefit under 35 U.S.C. § 119(e) of the priority date of U.S. Provisional Application Ser. No. 63/687,644; titled “ERROR RATE BASED DYNAMIC WEAR LEVELING TO IMPROVE THE DRIVE RELIABILITY WITH ENHANCED LIFETIME”; and filed August 27, 2024. The Provisional Application is hereby incorporated by reference, in its entirety, into the current patent application.

### TECHNICAL FIELD

Various examples of the present disclosure relate to dynamic wear leveling to improve reliability and extend a lifetime of a memory device.

### BACKGROUND

Virtual blocks of a memory device may undergo a number of program/erase (P/E) cycles during a lifetime of the memory device. Various manufacturers may establish a retirement threshold of P/E cycles of the virtual blocks. The virtual blocks may be retired when they undergo a number of P/E cycles exceeding the retirement threshold. When a virtual block is retired, data may be read from the virtual block, but new data may not be written to the virtual block (i.e. the retired virtual block is read-only). Conventional dynamic wear leveling techniques may enable the memory device to utilize virtual blocks having a low number of P/E cycles compared to virtual blocks that have undergone a relatively high number of P/E cycles such that the number of P/E cycles of each virtual block may reach the retirement threshold at a similar rate.

This background discussion is intended to provide information related to the present invention which is not necessarily prior art.

### SUMMARY OF THE INVENTION

According to various examples of the present disclosure, a data storage system may include a memory device and a controller. The memory device may include a plurality of virtual blocks. The controller may include at least one processor and a memory. The memory may include instructions stored thereon, that when that when executed by the at least one processor, cause the at least one processor to: monitor a number of program/erase cycles for the plurality of virtual blocks; collect read errors for the plurality of virtual blocks; select a virtual block of the plurality of virtual blocks to open based on the number of program/erase cycles and the collected read errors; and write data to the selected open virtual block.

According to various examples of the present disclosure, a computer-implemented method may include: monitoring a number of program/erase cycles for a plurality of virtual blocks; collecting read errors for the plurality of virtual blocks; selecting a virtual block of the plurality of virtual blocks to open based on the number of program/erase cycles and the collected read errors; and writing data to the selected open virtual block.

According to various examples of the present disclosure, non-transitory computer readable media may include instructions, that when executed by at least one processor, cause the at least one processor to: monitor a number of P/E cycles for a plurality of virtual blocks; collect read errors for the plurality of virtual blocks; generate error profiles for the plurality of virtual blocks; and perform dynamic wear leveling operations based on the generated error profiles.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an example system for dynamic wear leveling;

FIG. 2 illustrates an example computing system connected to a communication network;

FIG. 3 illustrates an example data storage system of the system of FIG. 1;

FIG. 4 illustrates an example non-volatile media (NVM) memory of the system of FIG. 1;

FIG. 5A illustrates an example chart of program/erase cycles for virtual blocks when dynamic wear leveling is implemented but error data is not considered when opening virtual blocks;

FIG. 5B illustrates an example chart of program/erase cycles for virtual blocks when dynamic wear leveling is implemented and error data is considered when opening virtual blocks;

FIG. 6 illustrates an example method for dynamic wear leveling using read error data; and

FIG. 7 illustrates another method for dynamic wear leveling using read error data.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms "exemplary," "by example," and "for example," means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In various examples of the present disclosure, dynamic wear leveling techniques may be used to extend a lifetime of a memory device. The memory device may be part of a data storage system. The data storage system may be connected to a host system. In various examples, the data storage system may be connected to the host system by wired or wireless means. In various examples, the data storage system may be connected to more than one host system, such as in a multi-tenant environment, without limitation.

The data storage system may include a controller and the memory device. The controller may be operable to manage storage and retrieval of data to and from the memory device. The host system may send data to the data storage system for storage in the memory device. The host system may send a read request to the data storage system. The read request may indicate data to be retrieved from the memory device and sent back to the host system. The controller may process the read request and retrieve the data from the memory device.

In various examples, the memory device may be a solid state drive (SSD) including a plurality of non-volatile memory (NVM) media (e.g., NAND-based memory media) for data storage. In various examples, the NVM media may include chip enable (CE) ports which may also be referred to as targets. Examples may be used in single-level cell (SLC) systems as DRAM buffering for persistent data storage, but can also be used in higher level cell systems, such as triple-level cell (TLC) systems and quadruple-level cell (QLC) systems. Applications include high performance computing (HPC), data transfer for AI, and data center solutions (DCS).

The NVM media may respectively include a local controller and a plurality of dies. Each die may be referred to as a logical unit (LUN). Each LUN may include a plurality of planes. Each plane may include a plurality of physical blocks.

The controller may organize the physical blocks of the NVM media into a plurality of virtual blocks. A virtual block is a collection of physical blocks across all LUNs. In various examples, a virtual block may be formed to include one physical block from each plane of each LUN. The size of a virtual block may be (# Channels) x (# Targets per channel) x (# LUNs per target) x (# planes per LUN) x (one (1) block/LUN). In an example, a virtual block may span sixteen (16) channels, eight (8) targets per channel, two (2) LUNs per target, and two (2) planes per LUN, for a total of five hundred twelve (512) physical blocks. The example memory device may support a plurality of virtual blocks respectively including five hundred twelve (512) physical blocks. Additionally, the example virtual block may be further segmented into smaller virtual blocks. For example, the example memory device may support four (4) virtual blocks having a respective size of one hundred twenty-eight (128) physical blocks. In another example, the memory device may support eight (8) virtual blocks having respective sizes of sixty-four (64) blocks. It would be appreciated by one of ordinary skill in the art that a memory device may include more or less channels, targets, LUNs, and planes without departing from the scope of the present disclosure. The virtual blocks may be formed to include more or less physical blocks depending on the capacity of the memory device.

Each physical block may include a plurality of physical pages. A virtual block comprises multiple virtual pages. A virtual page is a collection of physical pages across all LUNs in a virtual block. A virtual page may be a redundant array of independent disks (RAID) stripe which contains one or two XOR parity pages. A RAID is a way of storing the same data in different places on multiple SSDs to protect data in the case of a drive failure. The number of virtual pages in a virtual block is equal to the number of physical pages in a single block. Similarly, a virtual word line (VWL) is a collection of physical WLs across each plane of each LUN. A flash transition layer (FTL) of the controller may manage the physical blocks in a virtual block unit. The FTL may manage a list of virtual blocks according to their states (i.e., free, open, used).

In various examples, the controller may monitor program/erase (P/E) cycles of the plurality of virtual blocks. The number of P/E cycles of each virtual block may be compared to a retirement threshold. The retirement threshold may correspond to a number of P/E cycles that a virtual block may undergo before the virtual block may be retired. The retirement threshold may be variable based on a memory device type. The retirement threshold may be associated with a manufacturer retirement threshold set by a manufacturer of the memory device. The retirement threshold may vary from the manufacturer threshold without departing from the spirit of the present disclosure, for example where the retirement threshold is lower by 5%, 15%, 25%, or 50% than the manufacturer retirement threshold, such that dynamic wear leveling may be implemented to virtual blocks before reaching the manufacturer retirement threshold. In various examples, some virtual blocks may still be healthy after reaching the retirement threshold. The healthy virtual blocks may be utilized for data storage after the retirement threshold is reached. Accordingly, in some cases, automated manufacturer mechanisms may be disabled or replaced such that healthy virtual blocks may continue to be utilized after reaching the manufacturer retirement threshold.

For example, the retirement threshold may be three thousand (3,000) P/E cycles, without limitation. Unhealthy virtual blocks may be retired after undergoing three thousand (3,000) P/E cycles. Healthy virtual blocks may continue to be utilized until producing read errors exceeding the error threshold and/or satisfying criteria for the various types of errors. For example, a first healthy virtual block may reach three-thousand two-hundred fifty (3,250) P/E cycles, a second healthy virtual block may reach three-thousand one-hundred (3,100) P/E cycles, and a third healthy virtual block may reach three-thousand fifty (3,050) P/E cycles before being retired. Accordingly, the lifetime of the memory device may be extended by utilizing healthy virtual blocks even after the virtual blocks undergo a number of P/E cycles exceeding the retirement threshold.

In various examples, the health of each virtual block may be determined based on read error statistics of the virtual blocks. During operation, some of the physical blocks of the virtual blocks may produce read errors. The read errors may include uncorrectable read errors and correctable read errors. Uncorrectable read errors may include memory wear or endurance errors. Correctable read errors may include program disturb, read disturb, over-programming, and retention errors.

In various examples, the read errors may be collected by the controller. The collected read errors may include read error information. The read error information may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. Additionally or alternatively, the collected read errors may include information associated with the physical blocks, such as a program/erase cycle count, usage statistics, and/or other relevant information of the physical blocks.

In various examples, the controller may generate an error profile for each of the virtual blocks based on the collected read errors. The error profiles may indicate a health, status, and/or wear level of each virtual block. In various examples, the controller may determine virtual block health based on the error profiles. The controller may utilize the determined virtual block health to identify healthy virtual blocks that may be utilized for storing new data and unhealthy virtual blocks that may be retired or utilized less often than the healthy virtual blocks, while balancing the number of P/E cycles of the virtual blocks throughout the lifetime of the memory device. For example, a first virtual block that procures relatively few errors compared to a second virtual block may be considered to be a healthy virtual block, and the second virtual block may be determined to be an unhealthy virtual block that is subject to faster degradation than the first virtual block.

In various examples, the controller may perform dynamic wear leveling operations based on the error profiles to balance the P/E cycles of the virtual blocks while utilizing healthy virtual blocks more often than unhealthy virtual blocks. Dynamic wear leveling may include operations for selecting a virtual block to open. In various examples, data received from the host system may be written to an open virtual block. Accordingly, opening a virtual block may refer to selecting a virtual block to write host data to.

In conventional dynamic wear leveling techniques, the number of P/E cycles may be balanced among the virtual blocks such that each virtual block undergoes the same number of P/E cycles at any given point during the lifetime of the memory device. In various examples of the present disclosure, the virtual blocks may undergo different numbers of P/E cycles based on the error profiles. For example, at a first point in time, a first virtual block may have undergone one hundred (100) P/E cycles, a second virtual block may have undergone one hundred twenty (120) P/E cycles, and a third virtual block may have undergone ninety-five (95) P/E cycles. At a second point in time after the first point in time, the first virtual block may have undergone one thousand P/E cycles, the second virtual block may have undergone one-thousand one-hundred fifty (1150) P/E cycles, and the third virtual block may have undergone nine-hundred fifty (950) P/E cycles. In this example, the third virtual block may produce a greater number of errors than the first and second virtual blocks, and the second virtual block may produce a least amount of errors compared to the first and third virtual blocks. The controller may select the second virtual block to open more often than the first and third virtual blocks. Accordingly, the controller may utilize the error profiles when performing dynamic wear leveling to utilize healthy virtual blocks more often than unhealthy virtual blocks throughout the lifetime of the memory device, thereby extending the lifetime of the memory device and reducing latency and write amplification issues caused by unhealthy blocks.

The controller may identify virtual blocks having P/E cycles that exceed the retirement threshold or a number of P/E cycles approaching the retirement threshold. A first subset of the identified virtual blocks may be associated with a low error rate indicated by the error profiles. A second subset of the identified virtual blocks may be associated with a relatively high error rate indicated by the error profiles. The high error rate may be higher than the low error rate. The second subset of the identified virtual blocks may be unhealthy virtual blocks. The controller may determine healthy virtual blocks of the identified virtual blocks based on the collected read errors. The collected read errors for the healthy virtual blocks may not exceed an error threshold. In various examples, the error threshold may correspond to a number of errors, type of errors, and/or an amount of resources used to correct the errors for a given virtual block, without limitation. When the error threshold or criteria is/are exceeded for a given virtual block, the virtual block may be retired.

The controller may determine to open one of the healthy virtual blocks for storing data after the healthy virtual blocks have exceeded the retirement threshold, for example based on the error profiles for the healthy virtual blocks. As noted above, the second subset of the identified virtual blocks may be determined to be unhealthy virtual blocks based on the collected error information.

After the virtual blocks reach the retirement threshold, the controller may balance the number of P/E cycles across the healthy virtual blocks. For example, a healthy virtual block having a lowest number of P/E cycles of the healthy virtual blocks may be selected as the open virtual block. The unhealthy identified virtual blocks may be retired upon reaching the retirement threshold. When a virtual block is retired, the retired virtual block enters a read-only state. In the read-only state, data may be read from, but not written to, the retired virtual block.

Accordingly, performing dynamic wear leveling based on the error profiles may improve the reliability and extend the lifetime of the memory device by utilizing healthy virtual blocks more often than unhealthy virtual blocks throughout the lifetime of the memory device, including after the P/E cycles of the healthy virtual blocks exceed the retirement threshold. Additionally, preventing unhealthy virtual blocks from being opened or reducing a number of times the unhealthy blocks may be opened may reduce write amplification and read latency by avoiding error recover operations and virtual block refresh operations that occur when a bit-error rate of a given virtual block is high.

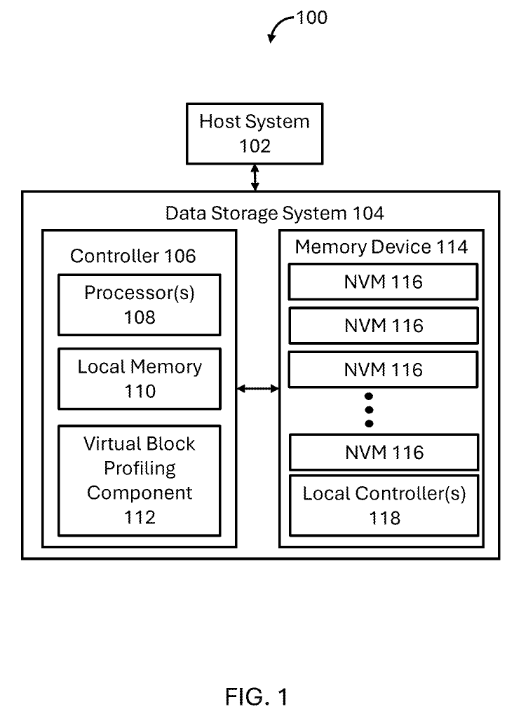

FIG. 1 illustrates an example system 100 including a host system 102 and a data storage system 104. The data storage system 104 may include a controller 106. The controller 106 may include a processor 108, a local memory 110, and a virtual block profiling component 112. The data storage system 104 may also include a memory device 114. The memory device 114 may include a plurality of non-volatile memory (NVM) media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to provide data protection and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

In various examples, the virtual block profiling component 112 may correspond to a flash transition layer (FTL) operable to manage virtual blocks of the NVM media 116. Each virtual block may include a plurality of physical blocks across all logical units (LUNs) of the NVM media 116. Each LUN may include a plurality of planes. Each plane may include subsets of the plurality of physical blocks. In an example, each virtual block may include one physical block from each plane of each LUN.

The virtual block profiling component 112 may monitor P/E cycles of each virtual block. The virtual block profiling component 112 may perform dynamic wear leveling operations to balance the P/E cycles of the virtual blocks while utilizing healthy virtual blocks more often than unhealthy virtual blocks throughout the lifetime of the memory device 114. The number of P/E cycles of each virtual block may be compared to a retirement threshold. The retirement threshold may correspond to a minimum number of P/E cycles that a virtual block may undergo before the virtual block may be retired. The retirement threshold may be variable based on a memory device type. The retirement threshold may be associated with a manufacturer retirement threshold set by a manufacturer of the memory device. The retirement threshold may vary from the manufacturer threshold without departing from the spirit of the present disclosure, for example where the retirement threshold is lower by 5%, 15%, 25%, or 50% than the manufacturer retirement threshold. In various examples, some virtual blocks may still be healthy after reaching the retirement threshold. The healthy virtual blocks may be utilized for data storage after the retirement threshold is reached. Accordingly, in some cases, automated manufacturer mechanisms may be disabled or replaced such that healthy virtual blocks may continue to be utilized after reaching the manufacturer retirement threshold.

The virtual block profiling component 112 may collect read errors produced by the physical blocks during read operations of the NVM media 116. The read operation may include a read operation performed in response to a request received form the host system 102 and/or a background scan performed by the virtual block profiling component 112. The background scan may perform background read operations to detect and collect read errors produced by respective virtual blocks of the plurality of virtual blocks.

The background scan may be performed periodically on a static or dynamic schedule, and/or as triggered by one or more events. The one or more events may include, without limitation, a predefined number of P/E cycles for all virtual blocks and/or a virtual block reaching the P/E retirement threshold or error threshold. For example, the read errors may be collected after each virtual block has undergone fifty (50) P/E cycles. The collected read errors may be utilized to determine a priority of virtual blocks to open over the next fifty (50) P/E cycles. Virtual blocks producing relatively fewer errors than other virtual blocks may be given priority such that the virtual blocks producing relatively fewer errors are opened more often than virtual blocks producing a relatively greater number of errors. Accordingly, the virtual block profiling component 112 may dynamically determine the priority of virtual blocks to open in a cyclical manner, such as after ten (10), twenty-five (25), fifty (50), one-hundred (100), and/or one hundred fifty (150) P/E cycles of the virtual blocks, without limitation.

The predefined number of P/E cycles may be static or dynamic. For example, the size of the interval between priority determinations for the virtual blocks may decrease as the number of P/E cycles undergone by the virtual blocks approaches the retirement threshold. It would be appreciated by one of ordinary skill in the art that various different background scans, such as a patrol read scan or another dedicated background read scan, may be utilized to collect the read errors. The collected read errors may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. The collected read errors may include additional information associated with the physical blocks of each virtual block, such as usage statistics and other relevant information of the physical blocks.

In various examples, the virtual block profiling component 112 may generate an error profile for each virtual block based on the collected read errors. In various examples, the virtual block profiling component 112 may determine virtual block health based on the error profiles. The virtual block profiling component 112 may utilize the determined virtual block health to identify healthy virtual blocks that may be utilized for storing new data and unhealthy virtual blocks that may be retired or utilized less often than the healthy virtual blocks, while balancing the number of P/E cycles of the virtual blocks throughout the lifetime of the memory device 114. For example, a first virtual block that procures relatively few errors compared to a second virtual block may be considered to be a healthy virtual block, and the second virtual block may be determined to be an unhealthy virtual block that is subject to faster degradation than the first virtual block.

The virtual block profiling component 112 may determine to open one of the virtual blocks for storing data based on the number of P/E cycles and the error profiles for the virtual blocks. The virtual block profiling component 112 may consider the error profiles when balancing the number of P/E cycles across the virtual blocks. Balancing the number of P/E cycles across the virtual blocks may include selecting virtual blocks to open based on the number of P/E cycles and the collected error information for the virtual blocks. For example, a virtual block having a lowest number of P/E cycles and a lowest number of errors may be selected as the open virtual block. In another example, a first virtual block may be associated with more P/E cycles but less errors than a second virtual block. In this example, the virtual block profiling component 112 may select the first virtual block to open based on the collected error information. Data may be written to the open virtual block.

The virtual block profiling component 112 may identify virtual blocks having undergone P/E cycles that exceed the retirement threshold. A first subset of the identified virtual blocks may be associated with a low error rate. The first subset may be healthy virtual blocks. A second subset of the identified virtual blocks may be associated with a high error rate. The high error rate may be greater than the low error rate. Accordingly, the first subset may be healthy virtual blocks, and the second subset may be unhealthy virtual blocks. The virtual block profiling component 112 may determine healthy virtual blocks of the identified virtual blocks based on the error profiles.

Throughout the lifetime of the memory device 114, relatively healthy virtual blocks may be opened more often than unhealthy virtual blocks. Unhealthy virtual blocks may be retired after undergoing a number of P/E cycles exceeding the retirement threshold. Healthy virtual blocks may continue to be utilized after undergoing a number of P/E cycles exceeding the retirement threshold. The collected read errors of the error profiles for the healthy virtual blocks may not exceed an error threshold and/or satisfy criteria for the various types of errors discussed in more detail above. In various examples, the error threshold and/or criteria may correspond or relate to standards or limits for any combination of a number of errors, type of errors, and/or an amount of resources used to correct the errors for a given virtual block, without limitation.

The virtual block profiling component 112 may apply corresponding weights to the collected error information and the number of P/E cycles when determining which virtual block to open. In various examples, the weights may be adjusted based on the number of P/E cycles undergone by the virtual blocks, a number and/or severity of read errors produced by the virtual blocks, and/or a state of the lifetime of the memory device 114. Additionally, the weights may be adjusted depending on a memory type of the NVM 116. For example, different memory types may be associated with different retirement thresholds and/or different error types. The different memory types may include, for example, MLC memory, TLC memory, QLC memory, and/or PLC memory, without limitation. In various examples, the weights may be a ratio between virtual block health and the number of P/E cycles undergone by each virtual block. The virtual block health may be determined based on the error profiles. For example, the virtual block health may be weighted higher for QLC memory types than TLC memory types. The virtual block profiling component 112 may utilize the weighted collected error information and the weighted number of P/E cycles to determine a priority of virtual blocks to open, such that virtual blocks producing less errors are opened more often than virtual blocks producing more errors, while balancing the number of P/E cycles across the virtual blocks.

When the error threshold is exceeded and/or the criteria for the various types of errors is satisfied for a given virtual block, the virtual block may be retired or used less often for storing new data. For example, an unhealthy virtual block may continue to be utilized after producing errors that exceed the error threshold and/or the criteria for the various types of errors is satisfied for the unhealthy virtual block. However, the unhealthy virtual block may be opened less often than healthy virtual blocks. When the number of P/E cycles for the unhealthy virtual block exceeds the retirement threshold, the unhealthy virtual block may be retired.

When a virtual block is retired, the virtual block profiling component 112 may issue a command to cause the retired virtual block to enter a read-only state. In the read-only state, data may be read from, but not written to, the retired virtual block.

A healthy virtual block may be opened more often than unhealthy virtual blocks throughout the lifetime of the memory device 114. When the number of P/E cycles for the healthy virtual block exceeds the retirement threshold, the healthy virtual block may continue to be opened for storing data. Accordingly, dynamic wear leveling based on the error profiles may improve the reliability and extend the lifetime of the memory device by utilizing healthy virtual blocks after the P/E cycles of the healthy virtual blocks exceed the retirement threshold. Additionally, preventing unhealthy virtual blocks from being opened or reducing a number of times the unhealthy blocks may be opened may reduce write amplification and read latency by avoiding error recover operations and virtual block refresh operations that occur when a bit-error rate of a given virtual block is high.

In various examples, instructions for executing the virtual block profiling component 112 may be stored in the local memory 110. Some or all functions of the virtual block profiling component 112 may be executed by the processor 108, the local controller(s) 118, other circuitry of the controller 106 and/or memory device 114, or a combination thereof.

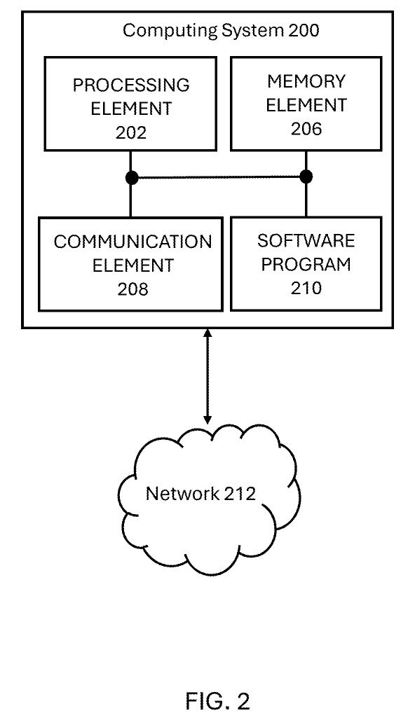

FIG. 2 illustrates a computing system 200 connected to a communication network 212. The computing system 200 may include at least one processing element 202, at least one memory element 206, a communication element 208, and a software program 210. In various examples, the computing system 200 may be a host system (e.g. the host system 102 of FIG. 1) and/or a data storage system (e.g. the data storage system 104 of FIG. 1), without limitation.

The software program 210 may be configured with instructions for performing and/or enabling performance of at least some of the steps set forth herein. In an embodiment, the software program 210 comprises instructions stored on computer-readable media of memory element 206. In various examples, the software program 210 may include instructions for performing operations of the virtual block profiling component 112 discussed with reference to FIG. 1.

The communication network 212 generally allows communication between the computing system 200 and another computing device, such as between a remote host system (e.g. the host system 102), a local host system, and/or a data storage system (e.g. the data storage system 104 of FIG. 1), without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard such as WiFi, IEEE 802.16 standard such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain embodiments, the communication element 208 may also couple with optical fiber cables. The communication element 208 may respectively be in communication with the processing element 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some embodiments, the memory element 206 may be embedded in, or packaged in the same package as, the processing element 202. The memory element 206 may include, or may constitute, a “computer-readable medium.” The memory element 206 may store the instructions, code, code segments, software, firmware, programs, applications, apps, services, daemons, or the like that are executed by the processing element 202. In an embodiment, the memory element 206 respectively store the software applications/program 210. The memory element 206 may also store settings, data, documents, sound files, photographs, movies, images, databases, and the like. In various examples, the memory element 206 may include a first memory component (e.g. the local memory 110 of FIG. 1) and one or more SSDs (e.g. the memory device 114 of FIG. 1).

The processing element 202 may include electronic hardware components such as processors. The processing element 202 may include digital processing unit(s). The processing element 202 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 202 may generally execute, process, or run instructions, code, code segments, software, firmware, programs, applications, apps, processes, services, daemons, or the like. For instance, the processing element 202 may execute the software applications/program 210. The processing element 202 may also include hardware components such as finite-state machines, sequential and combinational logic, and other electronic circuits that can perform the functions necessary for the operation of the current disclosure. The processing element 202 may be in communication with the other electronic components through serial or parallel links that include universal busses, address busses, data busses, control lines, and the like.

Through hardware, software, firmware, or various combinations thereof, the processing element 202 may – alone or in combination with other processing elements – be configured to perform the operations of embodiments of the present disclosure. The embodiments described herein in connection with the attached drawing figures are intended to describe aspects of the disclosure in sufficient detail to enable those skilled in the art to practice the disclosure. Other embodiments can be utilized and changes can be made without departing from the scope of the present disclosure. The system may include additional, less, or alternate functionality and/or device(s), including those discussed elsewhere herein. The above detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

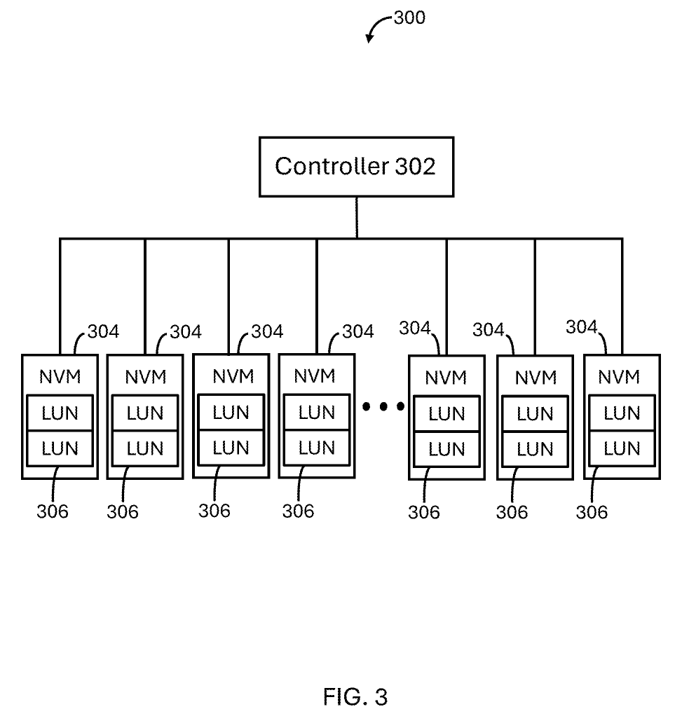

FIG. 3 illustrates an example data storage system 300 including a controller 302 and a plurality of NVM media 304. In various examples, the data storage system 300 may correspond to the data storage system 104 of FIG. 1, the controller 302 may correspond to the controller 106 of FIG. 1, and the NVM media 304 may correspond to the NVM media 116 of FIG. 1, without limitation. In various examples, the NVM media 304 may each include two LUNs 306. It would be appreciated by one of ordinary skill in the art that each of the NVM media 304 may include more than two LUNs 306 without departing from the scope of the present disclosure.

In various examples, a plurality of virtual blocks may be formed across each LUN 306 of each NVM 304. Each LUN 306 may include a plurality of planes. Each plane may include a plurality of physical blocks. Each virtual block may include one physical block of the plurality of physical blocks from each plane of each LUN 306 of each NVM 304.

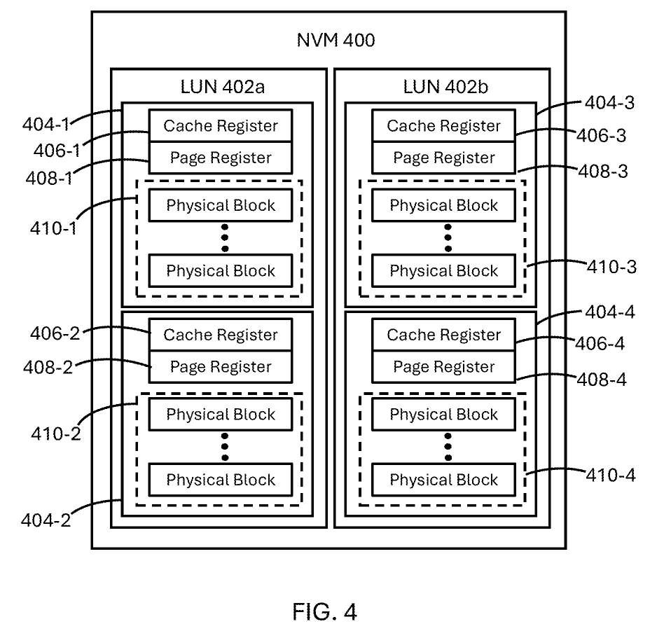

FIG. 4 illustrates an example NVM media 400. The NVM 400 may correspond to the NVM media 116 of FIG. 1, without limitation. The NVM media 400 may include a LUN 402a and a LUN 402b. The LUN 402a may include a plane 404-1 and a plane 404-2. The plane 404-1 may include a cache register 406-1, a page register 408-1, and physical blocks 410-1. The plane 404-2 may include a cache register 406-2, a page register 408-2, and physical blocks 410-2. The LUN 402b may include a plane 404-3 and a plane 404-4. The plane 404-3 may include a cache register 406-3, a page register 408-3, and physical blocks 410-3. The plane 404-4 may include a cache register 406-4, a page register 408-4, and physical blocks 410-4. It would be appreciated by one of ordinary skill in the art that the NVM media 400 may include more than two (2) die and each die may include more than two (2) planes. In various examples, the NVM media 400 may include two (2), four (4), eight (8), sixteen (16), twenty four (24), thirty two (32), or more die, without limitation. Each die may include, for example, four (4), six (6), eight (8), or more planes, without limitation.

When data is written to or retrieved from the LUN 402a or the LUN 402b, the data may be temporarily stored in one of the cache registers 406-1, 406-2, 406-3, 406-4 and/or the page registers 408-1, 408-2, 408-3, 408-4. The cache registers 406-1, 406-2, 406-3, 406-4 and the page registers 408-1, 408-2, 408-3, 408-4 may respectively have an equivalent data capacity of one page. Accordingly, data to be written to one page of one of the physical blocks 410-1 may be temporarily stored in the cache register 406-1 while data to be written to another page of one of the physical blocks 410-1 may be temporarily stored in the page register 408-1. Data to be read from a page of one of the physical blocks 410-1 may be retrieved and temporarily stored in one of the cache register 406-1 and the page register 408-1 while data to be written to a particular page may be stored in the other of the cache register 406-1 and the page register 408-1. Accordingly, the cache register and page register enable double buffering of data to reduce data programming and read times. Each page may include a plurality of cells. Data bits may be written to the plurality of cells on a page-by-page basis. Data may be erased from the plurality of cells on a physical block basis.

In various examples, one or more VBs may be formed across the planes 404-1, 404-2, 404-3, 404-4. A VB may include one (1) physical block 410-1 from the plane 404-1, one (1) physical block 410-2 from the plane 404-2, one (1) physical block 410-3 from the plane 404-3, and one (1) physical block 410-4 from the plane 404-4.

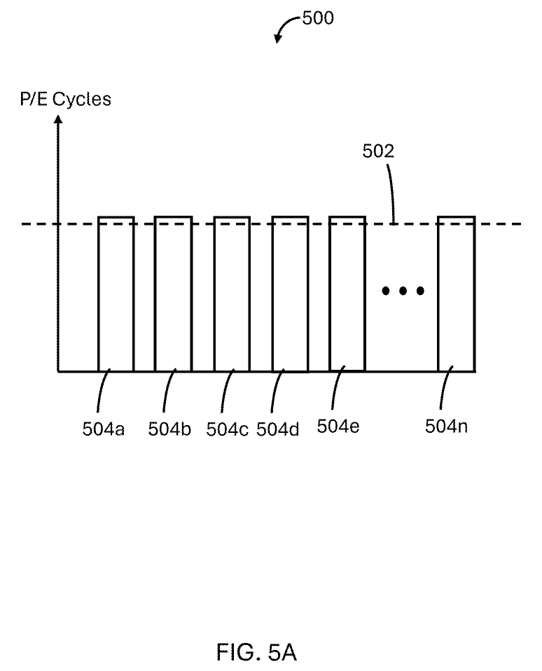

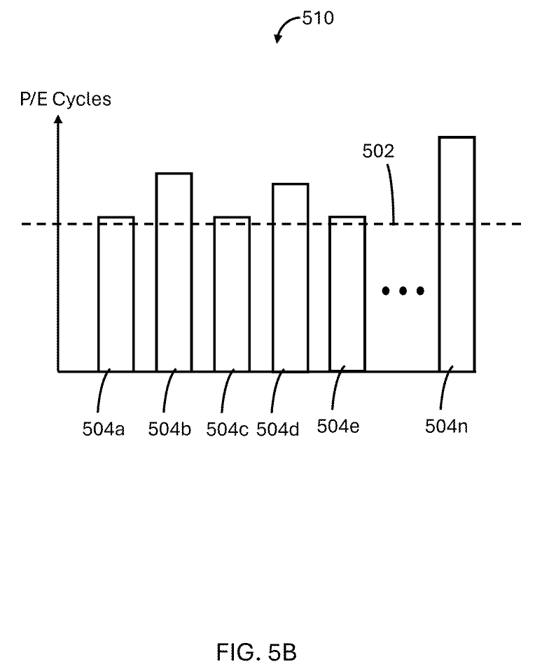

FIG. 5A illustrates an example chart 500 of P/E cycles of virtual blocks 504a, 504b, 504c, 504d, 504e, … 504n when dynamic wear leveling is implemented, but error data is not considered when opening respective virtual blocks of the virtual blocks 504a, 504b, 504c, 504d, 504e, … 504n. The virtual blocks 504a, 504b, 504c, 504d, 504e, … 504n may be in an end-of-life state. The end-of-life state may indicate that the virtual blocks 504a, 504b, 504c, 504d, 504e, … 504n may be approaching retirement. Virtual blocks of the virtual blocks 504a, 504b, 504c, 504d, 504e, … 504n may be selected to be opened based on the number of P/E cycles of the virtual blocks 504a, 504b, 504c, 504d, 504e, … 504n. Accordingly, a virtual block of the virtual blocks 504a, 504b, 504c, 504d, 504e, … 504n with a lowest number of P/E cycles may be selected to be opened. The virtual blocks 504a, 504b, 504c, 504d, 504e, … 504n may be formed within a plurality of NVM media, such as the NVM media of FIG. 1. The number of P/E cycles for each of the virtual blocks 504a, 504b, 504c, 504d, 504e, … 504n has exceeded a retirement threshold 502. When a threshold number of the virtual blocks 504a, 504b, 504c, 504d, 504e, … 504n, such as one half of the virtual blocks 504a, 504b, 504c, 504d, 504e, … 504n, are retired, all of the virtual blocks 504a, 504b, 504c, 504d, 504e, … 504n may be retired.

FIG. 5B illustrates an example chart 510 of P/E cycles of virtual blocks 504a, 504b, 504c, 504d, 504e, … 504n when dynamic wear leveling is implemented and error data is considered when opening respective virtual blocks. Virtual blocks of the virtual blocks 504a, 504b, 504c, 504d, 504e, … 504n may be selected to be opened based on a number of P/E cycles and collected read errors of the virtual blocks 504a, 504b, 504c, 504d, 504e, … 504n.The virtual blocks 504a, 504b, 504c, 504d, 504e, … 504n may be in an end-of-life state. The end-of-life state may indicate that the virtual blocks 504a, 504b, 504c, 504d, 504e, … 504n may be approaching retirement. The virtual blocks 504a, 504b, 504c, 504d, 504e, … 504n may be formed within a plurality of NVM media, such as the NVM media of FIG. 1. The number of P/E cycles for each of the virtual blocks 504a, 504b, 504c, 504d, 504e, … 504n has exceeded a retirement threshold 502. The virtual blocks 504a, 504c, and 504e may be unhealthy virtual blocks that have been retired. The virtual blocks 504b, 504d, … 504n may be healthy virtual blocks that may be utilized more often than the unhealthy virtual blocks 504a, 504c, and 504e. The healthy virtual blocks 504b, 504d, … 504n may be respectively utilized until read errors produced by respective ones of the healthy virtual blocks 504b, 504d, … 504n exceed an error threshold and/or satisfy criteria for various types of errors. Accordingly, utilizing the healthy virtual blocks 504b, 504d, … 504n more often than the unhealthy virtual blocks 504a, 504c, and 504e using dynamic wear leveling based on the error data may extend the lifetime of the plurality of NVM media compared to the conventional dynamic wear leveling shown in FIG. 5A.

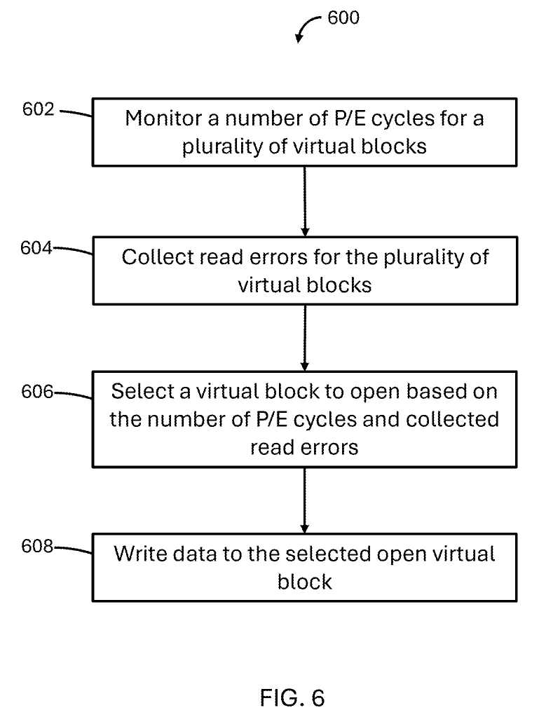

FIG. 6 illustrates an example method 600 for dynamic wear leveling using read error data. The method may be performed by a controller (e.g. the controller 106 and/or controller(s) 118 of FIG. 1) of a memory storage system (e.g. the data storage system 104 of FIG. 1). The controller may manage storage and retrieval of data to and from a memory device (e.g. the memory device 114 of FIG. 1). The controller may receive read and write requests from a host system. Upon receiving a write request, the controller may facilitate writing data received from the host system to the memory device. Upon receiving a read request, the controller may facilitate reading of data from the memory device and communication of the data to the host system.

The memory device may include a plurality of physical blocks. The controller may organize the physical blocks into a plurality of virtual blocks. The controller may generate and store a map of each virtual block. The map may include physical and/or logical addresses of the physical blocks making up each virtual block.

At operation 602, a number of P/E cycles for a plurality of virtual blocks may be monitored. The number of P/E cycles of each virtual block may be compared to a retirement threshold. The retirement threshold may correspond to a minimum number of P/E cycles that a virtual block may undergo before the virtual block may be retired. The retirement threshold may be variable based on a memory device type. The retirement threshold may be associated with a manufacturer retirement threshold set by a manufacturer of the memory device. The retirement threshold may vary from the manufacturer threshold without departing from the spirit of the present disclosure, for example where the retirement threshold is lower by 5%, 15%, 25%, or 50% than the manufacturer retirement threshold. In various examples, some virtual blocks may still be healthy after reaching the retirement threshold. The healthy virtual blocks may be utilized for data storage after the retirement threshold is reached. Accordingly, in some cases, automated manufacturer mechanisms may be disabled or replaced such that healthy virtual blocks may continue to be utilized after reaching the manufacturer retirement threshold.

At operation 604, read errors of the plurality of virtual blocks may be collected. A read error may be produced by a given physical block during a read operation. In various examples, a portion of the physical blocks may produce read errors during a read operation and other physical blocks may not produce read errors during the read operation. The read errors may be collected when performing a read operation associated with a read request received from the host. Additionally or alternatively, the controller may perform a background scan to collect the read errors. The background scan may perform background read operations to detect and collect read errors produced by respective physical blocks of the plurality of blocks.

The background scan may be performed periodically on a static or dynamic schedule, and/or as triggered by one or more events. The one or more events may include, without limitation, a predefined number of P/E cycles for all virtual blocks and/or a virtual block reaching the P/E retirement threshold or error threshold. For example, the read errors may be collected after each virtual block has undergone fifty (50) P/E cycles. The collected read errors may be utilized to determine a priority of virtual blocks to open over the next fifty (50) P/E cycles. Virtual blocks producing relatively fewer errors than other virtual blocks may be given priority such that the virtual blocks producing relatively fewer errors are opened more often than virtual blocks producing a relatively greater number of errors. Accordingly, the controller may dynamically determine the priority of virtual blocks to open in a cyclical manner, such as after ten (10), twenty-five (25), fifty (50), one-hundred (100), and/or one hundred fifty (150) P/E cycles of the virtual blocks, without limitation.

The predefined number of P/E cycles may be static or dynamic. For example, the size of the interval between priority determinations for the virtual blocks may decrease as the number of P/E cycles undergone by the virtual blocks approaches the retirement threshold. It would be appreciated by one of ordinary skill in the art that various different background scans, such as a patrol read scan or another dedicated background read scan, may be utilized to collect the read errors.

The virtual block may include a first subset of the plurality of physical blocks. The collected read errors may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. The collected read errors may include additional information associated with the physical blocks, such as usage statistics and/or other relevant information.

The read errors may be compared to an error threshold or criteria. In various examples, the error threshold may correspond to and/or define a number of errors, type of errors, and/or an amount of resources used to correct the errors for a given virtual block, without limitation.

When the error threshold is exceeded for a given virtual block, the virtual block may be retired or utilized less often than healthy virtual blocks. For example, an unhealthy virtual block may be utilized less often than healthy virtual blocks until undergoing a number of P/E cycles exceeding the retirement threshold. After the number of P/E cycles for the unhealthy virtual block exceeds the retirement threshold, the unhealthy virtual block may be retired. Healthy virtual blocks may produce an amount of read errors that do not exceed the error threshold.

An error profile for each virtual block may be determined based on the monitored P/E cycles and collected read errors. Healthy and unhealthy virtual blocks may be identified based on the error profiles. In various examples, the controller may determine virtual block health based on the error profiles. The controller may utilize the determined virtual block health to identify healthy virtual blocks that may be utilized for storing new data and unhealthy virtual blocks that may be retired or utilized less often than the healthy virtual blocks, while balancing the number of P/E cycles of the virtual blocks throughout the lifetime of the memory device. For example, a first virtual block that procures relatively few errors compared to a second virtual block may be considered to be a healthy virtual block, and the second virtual block may be determined to be an unhealthy virtual block that is subject to faster degradation than the first virtual block.

At operation 606, a virtual block of the plurality of virtual blocks may be selected to open based on the number of P/E cycles and the collected read errors. The controller may consider the error profiles and/or the collected read errors when balancing the number of P/E cycles across the virtual blocks. For example, a virtual block having a lowest number of P/E cycles and a lowest number of errors may be selected as the open virtual block. In another example, a first virtual block may be associated with more P/E cycles but less errors than a second virtual block. In this example, the controller may select the first virtual block to open based on the collected error information.

The controller may apply corresponding weights to the collected error information and the number of P/E cycles when determining which virtual block to open. In various examples, the weights may be adjusted based on the number of P/E cycles undergone by the virtual blocks, a number and/or severity of read errors produced by the virtual blocks, and/or a state of the lifetime of the memory device. Additionally, the weights may be adjusted depending on a memory type of the memory device. For example, different memory types may be associated with different retirement thresholds and/or different error types. The different memory types may include, for example, MLC memory, TLC memory, QLC memory, and/or PLC memory, without limitation. In various examples, the weights may be a ratio between virtual block health and the number of P/E cycles undergone by each virtual block. The virtual block health may be determined based on the error profiles. For example, the virtual block health may be weighted higher for QLC memory types than TLC memory types. The controller may utilize the weighted collected error information and the weighted number of P/E cycles to determine a priority of virtual blocks to open, such that virtual blocks producing less errors are opened more often than virtual blocks producing more errors, while balancing the number of P/E cycles across the virtual blocks.

In various examples, the number of P/E cycles of the selected open virtual block may exceed the retirement threshold at the time of the selection. If the number of P/E cycles of the selected open virtual block exceeds the retirement threshold at the time of the selection, the collected read errors of the open virtual block may not exceed the error threshold. The number of P/E cycles and/or a number of collected errors associated with the selected open virtual block may be less than the number of P/E cycles and/or number of collected errors associated with other healthy virtual blocks. For example, a first virtual block may be associated with a first number of errors and a first number of P/E cycles. A second virtual block may be associated with a second number of errors and a second number of P/E cycles. The first number of P/E cycles may be greater than the second number of P/E cycles. The first number of errors may be less than the second number of P/E cycles. The first virtual block may be selected to be opened.

At operation 608, data may be written to the selected open virtual block. The controller may, for example after the data is written to the selected open virtual block, choose a second virtual block to open. The second virtual block may be determined based on the error profiles and/or the determined priority. Accordingly, the controller may continue opening virtual blocks based on the error profiles and/or the determined priority. After the virtual blocks have undergone the predetermined number of P/E cycles, the controller may determine a new priority based on read errors collected after the previous priority was determined. Accordingly, the controller may perform dynamic wear leveling based on the collected read errors throughout the lifetime of the memory device. In various examples, the healthy virtual blocks may continue to be utilized even after the number of P/E cycles of the healthy virtual blocks have exceeded the retirement threshold, thus extending the lifetime of the memory device.

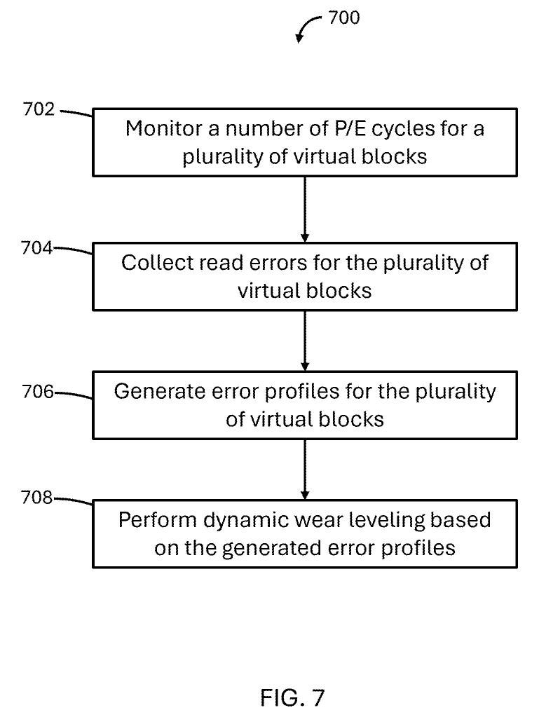

FIG. 7 illustrates an example method 700 for dynamic wear leveling using read error data. The method may be performed by a controller (e.g. the controller 106 and/or controller(s) 118 of FIG. 1) of a memory storage system (e.g. the data storage system 104 of FIG. 1). The method may be performed in connection with the method 600 of FIG. 6, for example prior to operation 606, without limitation. The controller may manage storage and retrieval of data to and from a memory device (e.g. the memory device 114 of FIG. 1). The controller may receive read and write requests from a host system. Upon receiving a write request, the controller may facilitate writing data received from the host system to the memory device. Upon receiving a read request, the controller may facilitate reading of data from the memory device and communication of the data to the host system.

The memory device may include a plurality of physical blocks. The controller may organize the physical blocks into a plurality of virtual blocks. The controller may generate and store a map of each virtual block. The map may include physical and/or logical addresses of the physical blocks making up each virtual block.

At operation 702, a number of P/E cycles for a plurality of virtual blocks may be monitored. The number of P/E cycles of each virtual block may be compared to a retirement threshold. The retirement threshold may correspond to a minimum number of P/E cycles that a virtual block may undergo before the virtual block may be retired. The retirement threshold may be variable based on a memory device type. The retirement threshold may be associated with a manufacturer retirement threshold set by a manufacturer of the memory device. The retirement threshold may vary from the manufacturer threshold without departing from the spirit of the present disclosure, for example where the retirement threshold is lower by 5%, 15%, 25%, or 50% than the manufacturer retirement threshold. In various examples, some virtual blocks may still be healthy after reaching the retirement threshold. The healthy virtual blocks may be utilized for data storage after the retirement threshold is reached. Accordingly, in some cases, automated manufacturer mechanisms may be disabled or replaced such that healthy virtual blocks may continue to be utilized after reaching the manufacturer retirement threshold.

At operation 704, read errors of the plurality of virtual blocks may be collected. A read error may be produced by a given physical block during a read operation. In various examples, a portion of the physical blocks may produce read errors during a read operation and other physical blocks may not produce read errors during the read operation. The read errors may be collected when performing a read operation associated with a read request received from the host. Additionally or alternatively, the controller may perform a background scan to collect the read errors. The background scan may perform background read operations to detect and collect read errors produced by respective physical blocks of the plurality of blocks.

The background scan may be performed periodically on a static or dynamic schedule, and/or as triggered by one or more events. The one or more events may include, without limitation, a predefined number of P/E cycles for all virtual blocks and/or a virtual block reaching the P/E retirement threshold or error threshold. For example, the read errors may be collected after each virtual block has undergone fifty (50) P/E cycles. The collected read errors may be utilized to determine a priority of virtual blocks to open over the next fifty (50) P/E cycles. Virtual blocks producing relatively fewer errors than other virtual blocks may be given priority such that the virtual blocks producing relatively fewer errors are opened more often than virtual blocks producing a relatively greater number of errors. Accordingly, the controller may dynamically determine the priority of virtual blocks to open in a cyclical manner, such as after ten (10), twenty-five (25), fifty (50), one-hundred (100), and/or one hundred fifty (150) P/E cycles of the virtual blocks, without limitation.

The predefined number of P/E cycles may be static or dynamic. For example, the size of the interval between priority determinations for the virtual blocks may decrease as the number of P/E cycles undergone by the virtual blocks approaches the retirement threshold. It would be appreciated by one of ordinary skill in the art that various different background scans, such as a patrol read scan or another dedicated background read scan, may be utilized to collect the read errors.

The virtual block may include a first subset of the plurality of physical blocks. The collected read errors may include a number of uncorrectable read errors, a number of correctable read errors, a number of error bits in each of the correctable errors, and error correction data for each physical block. The error correction data may include a number of steps, an amount of time, and/or a required complexity to correct corrupted data from a given physical block. The collected read errors may include additional information associated with the physical blocks, such as usage statistics and/or other relevant information.

The read errors may be compared to an error threshold or criteria. In various examples, the error threshold may correspond to and/or define a number of errors, type of errors, and/or an amount of resources used to correct the errors for a given virtual block, without limitation.

When the error threshold is exceeded for a given virtual block, the virtual block may be retired or utilized less often than healthy virtual blocks. For example, an unhealthy virtual block may be utilized less often than healthy virtual blocks until undergoing a number of P/E cycles exceeding the retirement threshold. After the number of P/E cycles for the unhealthy virtual block exceeds the retirement threshold, the unhealthy virtual block may be retired. Healthy virtual blocks may produce an amount of read errors that do not exceed the error threshold.

At operation 706, error profiles for the plurality of virtual blocks may be determined based on the collected read errors. In various examples, the controller may determine virtual block health based on the error profiles. The controller may utilize the determined virtual block health to identify healthy virtual blocks that may be utilized for storing new data and unhealthy virtual blocks that may be retired or utilized less often than the healthy virtual blocks, while balancing the number of P/E cycles of the virtual blocks throughout the lifetime of the memory device. For example, a first virtual block that procures relatively few errors compared to a second virtual block may be considered to be a healthy virtual block, and the second virtual block may be determined to be an unhealthy virtual block that is subject to faster degradation than the first virtual block.

The error profiles may be updated for each virtual block after undergoing a second predefined number of P/E cycles. The second predefined number of P/E cycles may or may not be the same as the predefined number of P/E cycles. In one example, the predefined number of P/E cycles may be the same throughout the lifetime of the memory device. In another example, the predefined number of P/E cycles may be adjusted dynamically, such as being reduced throughout the lifetime of the memory device. The updated error profiles may include read errors and other error information collected subsequent to determining the previous error profiles. Accordingly, the error profiles may be updated throughout the lifetime of the memory device, for example, each time the virtual blocks undergo a static or dynamic number of P/E cycles. Additionally, preventing unhealthy virtual blocks from being opened or reducing a number of times the unhealthy blocks may be opened may reduce write amplification and read latency by avoiding error recover operations and virtual block refresh operations that occur when a bit-error rate of a given virtual block is high.

At operation 708, dynamic wear leveling operations may be performed based on the generated error profiles. The wear leveling operations may include dynamically determining virtual block health based on the generated error profiles, determining a priority of virtual blocks to open based on the virtual block health, and selecting virtual blocks to open based on the determined priority, without limitation. Virtual block health may be determined based on the error profiles. For example, a healthy virtual block may produce relatively few errors compared to unhealthy virtual blocks. Unhealthy virtual blocks may produce a relatively large number of errors or relatively costly errors compared to healthy virtual blocks. The priority may be determined based on the determined virtual block health. The priority of virtual blocks may include an ordered list or table of virtual blocks based on the error profiles. For example, healthy virtual blocks may be given priority over unhealthy virtual blocks, such that healthy blocks may be selected to be opened more often than unhealthy virtual blocks. The priority may be dynamically updated, for example each time the virtual blocks undergo the predefined number of P/E cycles, such that healthy virtual blocks may be utilized more often than unhealthy blocks throughout the lifetime of the memory device.

In various examples, the virtual blocks may undergo different number of P/E cycles throughout the lifetime of the memory device according to the priority determined from the error profiles. For example, at a first point in time, a first virtual block may have undergone one hundred (100) P/E cycles, a second virtual block may have undergone one hundred twenty (120) P/E cycles, and a third virtual block may have undergone ninety-five (95) P/E cycles. At a second point in time after the first point in time, the first virtual block may have undergone one thousand P/E cycles, the second virtual block may have undergone one-thousand one-hundred fifty (1150) P/E cycles, and the third virtual block may have undergone nine-hundred fifty (950) P/E cycles. In this example, the third virtual block may produce a greater number of errors than the first and second virtual blocks, and the second virtual block may produce a least amount of errors compared to the first and third virtual blocks. The controller may select the second virtual block to open more often than the first and third virtual blocks. Accordingly, the controller may utilize the error profiles when performing dynamic wear leveling to utilize healthy virtual blocks more often than unhealthy virtual blocks throughout the lifetime of the memory device, thereby extending the lifetime of the memory device and reducing latency and write amplification issues caused by unhealthy blocks.

In another example, the retirement threshold may be three thousand (3,000) P/E cycles, without limitation. Unhealthy virtual blocks may be retired after undergoing three thousand (3,000) P/E cycles. Healthy virtual blocks may continue to be utilized until producing read errors exceeding the error threshold and/or satisfying criteria for the various types of errors. For example, a first healthy virtual block may reach three-thousand two-hundred fifty (3,250) P/E cycles, a second healthy virtual block may reach three-thousand one-hundred (3,100) P/E cycles, and a third healthy virtual block may reach three-thousand fifty (3,050) P/E cycles before being retired. Accordingly, the lifetime of the memory device may be extended by utilizing healthy virtual blocks even after the virtual blocks undergo a number of P/E cycles exceeding the retirement threshold.

According to various examples of the present disclosure, a data storage system may include a memory device and a controller. The memory device may include a plurality of virtual blocks. The controller may include at least one processor and a memory. The memory may include instructions stored thereon, that when that when executed by the at least one processor, cause the at least one processor to: monitor a number of P/E cycles for the plurality of virtual blocks; collect read errors for the plurality of virtual blocks; select a virtual block of the plurality of virtual blocks to open based on the number of P/E cycles and the collected read errors; and write data to the selected open virtual block.

In combination with any of the previous examples, the selection of the open virtual block based in part on the collected read errors may be based at least in part on a determination that the number of P/E cycles of the open virtual block exceeded a retirement threshold.

In combination with any of the previous examples, at the time of the selection, the collected read errors of the open virtual block do not exceed an error threshold.

In combination with any of the previous examples, the collected read errors may be collected during one of: respective read operations, one or more background scans, and a combination thereof.

In combination with any of the previous examples, the collected read errors may include a number of uncorrectable read errors, a number of correctable read errors, a number of error bits in each of the correctable read errors, and error correction data.

In combination with any of the previous examples, the error correction data may include a number of steps required to correct data for each error of the collected read errors. According to various examples of the present disclosure, a computer-implemented method may include: monitoring a number of P/E cycles for a plurality of virtual blocks; collecting read errors for the plurality of virtual blocks; selecting a virtual block of the plurality of virtual blocks to open based on the number of P/E cycles and the collected read errors; and writing data to the selected open virtual block.

According to various examples of the present disclosure, non-transitory computer readable media may include instructions, that when executed by at least one processor, cause the at least one processor to: monitor a number of P/E cycles for a plurality of virtual blocks; collect read errors for the plurality of virtual blocks; generate error profiles for the plurality of virtual blocks; and perform dynamic wear leveling operations based on the generated error profiles.

In combination with any of the previous examples, the error profiles may be generated after the plurality of virtual blocks undergo a predetermined number of P/E cycles.

In combination with any of the previous examples, the error profiles may be updated after the plurality of virtual blocks undergo a second predefined number of P/E cycles.

In combination with any of the previous examples, the dynamic wear leveling operations may include: determining a virtual block health of the plurality of virtual blocks based on the generated error profiles; and determining a priority of the plurality of virtual blocks to open based on the determined virtual bock health.

In combination with any of the previous examples, the instructions, when executed by the at least one processor, may cause the at least one processor to: select a virtual block of the plurality of virtual blocks to open based on the determined priority.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A data storage system comprising:
a memory device including a plurality of virtual blocks; and
a controller including at least one processor and a memory, said memory including instructions stored thereon, that when executed by the at least one processor, cause the at least one processor to:
monitor a number of program/erase cycles for the plurality of virtual blocks;
collect read errors for the plurality of virtual blocks;
select a virtual block of the plurality of virtual blocks to open based on the number of P/E cycles and the collected read errors; and
write data to the selected open virtual block.

2. The data storage system of claim 1,
wherein the selection of the open virtual block based in part on the collected read errors is based at least in part on a determination that the number of P/E cycles of the open virtual block exceeded a retirement threshold.

3. The data storage system of claim 2,
wherein at the time of the selection the collected read errors of the open virtual block do not exceed an error threshold.

4. The data storage system of claim 1,
wherein the collected read errors are collected during one of: respective read operations, one or more background scans, and a combination thereof.

5. The data storage system of claim 1,
wherein the collected read errors include a number of uncorrectable read errors, a number of correctable read errors, a number of error bits in each of the correctable read errors, and error correction data.

6. The data storage system of claim 5,
wherein the error correction data includes a number of steps required to correct data for each error of the collected read errors.

7. A computer-implemented method, comprising:
monitoring a number of program/erase (P/E) cycles for a plurality of virtual blocks;
collecting read errors for the plurality of virtual blocks;
selecting a virtual block of the plurality of virtual blocks to open based on the number of program/erase cycles and the collected read errors; and
writing data to the selected open virtual block.

8. The computer-implemented method of claim 7,
wherein the selection of the open virtual block based in part on the collected read errors is based at least in part on a determination that the number of P/E cycles of the open virtual block exceeded a retirement threshold.

9. The computer-implemented method of claim 8,
wherein at the time of the selection the collected read errors of the open virtual block do not exceed an error threshold.

10. The computer-implemented method of claim 7,
wherein the read errors are collected during one of: respective read operations, one or more background scans, and a combination thereof.

11. The computer-implemented method of claim 7,
wherein the collected read errors include a number of uncorrectable read errors, a number of correctable read errors, a number of error bits in each of the correctable read errors, and error correction data.

12. The computer-implemented method of claim 11,
wherein the error correction data includes a number of steps required to correct data for each error of the collected errors.

13. Non-transitory computer readable media having instructions stored thereon, that when executed by at least one processor, cause the at least one processor to:
monitor a number of program/erase (P/E) cycles for a plurality of virtual blocks;
collect read errors for the plurality of virtual blocks;
generate error profiles for the plurality of virtual blocks; and
perform dynamic wear leveling operations based on the generated error profiles.

14. The non-transitory computer readable media of claim 13,
wherein the error profiles are generated after the plurality of virtual blocks undergo a predetermined number of P/E cycles.

15. The non-transitory computer readable media of claim 14,
wherein the error profiles are updated after the plurality of virtual blocks undergo a second predefined number of P/E cycles.

16. The non-transitory computer readable media of claim 13,
wherein the dynamic wear leveling operations include:
determining a virtual block health of the plurality of virtual blocks based on the generated error profiles; and
determining a priority of the plurality of virtual blocks to open based on the determined virtual block health.

17. The non-transitory computer readable media of claim 16,
wherein the instructions, when executed by the at least one processor, cause the at least one processor to:
select a virtual block of the plurality of virtual blocks to open based on the determined priority.

18. The non-transitory computer readable media of claim 13,
wherein the collected read errors include a number of uncorrectable read errors, a number of correctable read errors, a number of error bits in each of the correctable read errors, and error correction data.

19. The non-transitory computer readable media of claim 18,
wherein the collected read errors are collected during one of: respective read operations, one or more background scans, and a combination thereof.

20. The non-transitory computer readable media of claim 18,
wherein the error correction data includes a number of steps required to correct data for each error of the collected read errors.
